(19) United States
(12) Patent Application Publication
(10) Pub. No.: US 2012/0325302 A1
(43) Pub. Date: Dec. 27, 2012

(54) PHOTOVOLTAIC DEVICE INCLUDING FLEXIBLE OR INFLEXIBLE SUBSTRATE AND METHOD FOR MANUFACTURING THE SAME

(76) Inventor: Seung-Yeop Myong, Seoul (KR)

(21) Appl. No.: 13/603,001

(22) Filed: Sep. 4, 2012

Related U.S. Application Data
(62) Division of application No. 13/071,191, filed on Mar. 24, 2011.

(30) Foreign Application Priority Data
Mar. 26, 2010 (KR) 10-2010-0027397

(51) Int. Cl. H01L 31/065; H01L 31/18

(52) U.S. Cl. 136/255; 438/87; 257/E31.061

(57) ABSTRACT

Disclosed is a photovoltaic device. The photovoltaic device according to the present invention includes: a first electrode; a second electrode; and a p-type window layer, a buffer layer, a light absorbing layer and an n-type layer, which are sequentially stacked between the first electrode and the second electrode, wherein, when the p-type window layer is composed of hydrogenated amorphous silicon oxide, the buffer layer is composed of either hydrogenated amorphous silicon carbide or hydrogenated amorphous silicon oxide, and wherein, when the p-type window layer is composed of hydrogenated amorphous silicon carbide, the buffer layer is composed of hydrogenated amorphous silicon oxide.

### CROSS-REFERENCE TO RELATED APPLICATIONS

This application is a divisional of U.S. patent application Ser. No. 13/071,191, filed on Mar. 24, 2011, which claims priority under 35 U.S.C. §119 to Korean Patent Application No. 10-2010-0027397, filed on Mar. 26, 2010, the entireties of which are hereby incorporated by reference.

### FIELD OF THE INVENTION

The present invention relates to a photovoltaic device including a flexible substrate or an inflexible substrate and a method for manufacturing the same.

### BACKGROUND OF THE INVENTION

Since an amorphous silicon (a-Si) photovoltaic device was first developed in 1976, it has been widely researched because hydrogenated amorphous silicon (a-Si:H) has a high photosensitivity in a visible light region, easy controllability of an optical band gap and processibility at a low price and a low temperature and of a wide area.

However, it was discovered that the hydrogenated amorphous silicon (a-Si:H) suffers from Stabler-Wronski effect. That is to say, the hydrogenated amorphous silicon (a-Si:H) has a fatal disadvantage of significant degradation by light exposure.

Therefore, many efforts have been made to reduce the Stabler-Wronski effect of amorphous silicon based material. As a result a method of performing H₂ dilution of SiH₄ was developed.

Meanwhile, in order to develop a thin film photovoltaic device with high efficiency, it is necessary to provide not only alight absorbing layer with a small degradation rate but also a p-type window layer which generates a strong electric field in the light absorbing layer and absorbs minimal visible light by itself. Accordingly, extensive researches on the p-type window layer and a buffer layer are being carried out.

### SUMMARY OF THE INVENTION

One aspect of the present invention is a photovoltaic device. The photovoltaic device includes: a first electrode; a second electrode; and a p-type window layer, a buffer layer, a light absorbing layer and an n-type layer, which are sequentially stacked between the first electrode and the second electrode, wherein, when the p-type window layer is composed of hydrogenated amorphous silicon oxide, the buffer layer is composed of either hydrogenated amorphous silicon carbide or hydrogenated amorphous silicon oxide, and wherein, when the p-type window layer is composed of hydrogenated amorphous silicon carbide, the buffer layer is composed of hydrogenated amorphous silicon oxide.

Another aspect of the present invention is a method for manufacturing a photovoltaic device. The method, includes: forming a first electrode; forming a p-type window layer, a buffer layer, a light absorbing layer and an n-type layer, which are sequentially stacked on the first electrode in the order listed from a light incident side; and forming a second electrode on the p-type window layer, the buffer layer, the light absorbing layer and the n-type layer, which are sequentially stacked from the light incident side, wherein, when the p-type window layer is composed of hydrogenated amorphous silicon oxide, the buffer layer is composed of either hydrogenated amorphous silicon carbide or hydrogenated amorphous silicon oxide, and wherein, when the p-type window layer is composed of hydrogenated amorphous silicon carbide, the buffer layer is composed of hydrogenated amorphous silicon oxide.

### BRIEF DESCRIPTION OF THE DRAWINGS

FIGS. 1a and 1b are cross sectional views of a p-i-n type thin film photovoltaic device and an n-i-p type thin film photovoltaic device according to an embodiment of the present invention.

FIG. 2 shows a method for manufacturing a p-type window layer of the photovoltaic device according to the embodiment of the present invention.

FIG. 3 shows a method for manufacturing a p-type buffer layer of the photovoltaic device according to the embodiment of the present invention.

### DETAILED DESCRIPTION

Hereinafter, said silicon thin film photovoltaic device and a method for manufacturing the same will be described in detail with reference to the accompanying drawings.

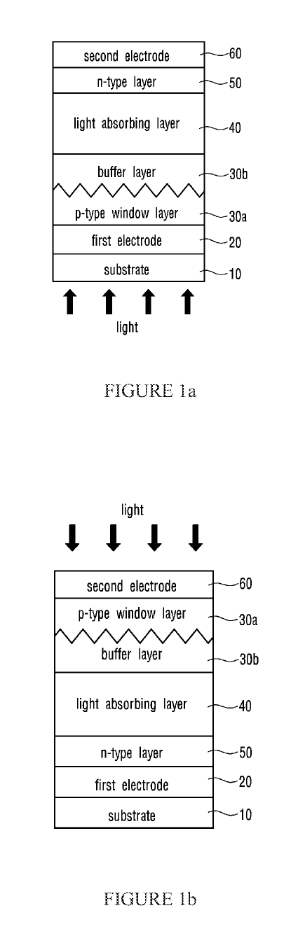

FIGS. 1a and 1b are cross sectional views of a p-i-n type thin film photovoltaic device and an n-i-p type thin film photovoltaic device according to an embodiment of the present invention.

As shown in FIGS. 1a and 1b, a photovoltaic device according to the embodiment of the present invention includes a substrate 10, a first electrode 20, a p-type window layer 30a, a buffer layer 30b, a light absorbing layer 40, an n-type layer 50 and a second electrode 60.

The photovoltaic device according to the embodiment of the present invention includes the p-type window layer 30a, buffer layer 30b, light absorbing layer 40 and n-type layer 50, which are sequentially stacked from an electrode on which light is first incident among the first electrode 20 and the second electrode 60.

That is, in the p-i-n type photovoltaic device, light is incident through the substrate 10 and the first electrode 20. Therefore, the p-i-n type photovoltaic device includes the p-type window layer 30a, buffer layer 30b, light absorbing layer 40 and n-type layer 50, which are sequentially stacked from the first electrode 20.

In the n-i-p type photovoltaic device, light is incident through the second electrode 60. Therefore, the n-i-p type photovoltaic device includes the p-type window layer 30a, buffer layer 30b, light absorbing layer 40 and n-type layer 50, which are sequentially stacked from the second electrode 60.

The substrate 10 of the photovoltaic device according to the embodiment of the present invention is either a flexible substrate such as a metal foil or polymer or an inflexible substrate such as glass.

The first electrode 20 of the p-i-n type photovoltaic device and the second electrode 60 of the n-i-p type photovoltaic device have a high transmittance. The first electrode 20 or the second electrode 60 which is light transmissive may be formed of a transparent conductive oxide, for example, ZnO. When the transparent conductive oxide is formed by means of a chemical vapor deposition, the surface of the transparent conductive oxide may be textured. The textured surface of the transparent conductive oxide improves a light trapping effect.

Meanwhile, the second electrode 60 of the p-i-n type photovoltaic device and the first electrode 20 of the n-i-p type photovoltaic device may be formed of a metallic material deposited by a sputtering method.

The p-type window layer 30a is formed of slightly hydrogen-diluted amorphous silicon carbide (p-a-SiC:H) or slightly hydrogen-diluted amorphous silicon oxide (p-a-SiO:H).

Here, the buffer layer 30b is relatively more highly hydrogen-diluted than the p-type window layer 30a for the purpose of high efficiency of the photovoltaic device. The hydrogen concentration of the buffer layer 30b is hereby greater than that of the p-type window layer 30a. Further, the impurity concentration of the buffer layer 30b is less than that of the p-type window layer 30a. Here, hydrogen contents of the p-type window layer 30a and the buffer layer 30b are equal to or more than 10 atomic % and equal to or less than 25 atomic %. In addition, the impurity concentration of the p-type window layer 30a is equal to or greater than 1×10¹⁹ cm⁻³ and equal to or less than 1×10²¹ cm⁻³. The impurity concentration of the buffer layer 30b is equal to or greater than 1×10¹⁶ cm⁻³ and equal to or less than 5×10¹⁹ cm⁻³.

For example, when the p-type window layer 30a is composed of hydrogenated amorphous silicon oxide, the buffer layer 30b is composed of either hydrogenated amorphous silicon carbide or hydrogenated amorphous silicon oxide. Also, when the p-type window layer 30a is composed of hydrogenated amorphous silicon carbide, the buffer layer 30b is composed of hydrogenated amorphous silicon oxide. Here, the buffer layer 30b is more highly hydrogen-diluted than the p-type window layer 30a. The impurity concentration of the buffer layer 30b is less than both the impurity concentration of the p-type window layer 30a and oxygen concentration or carbon concentration of the p-type window layer 30a.

Hereinafter, a method for manufacturing the photovoltaic device including the p-type window layer 30a and the buffer layer 30b will be described in detail with reference to the drawings.

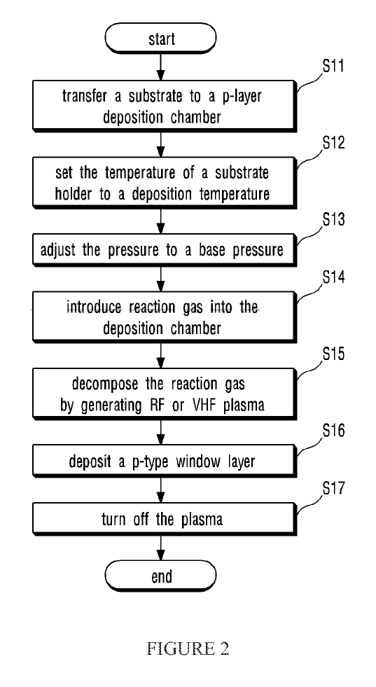

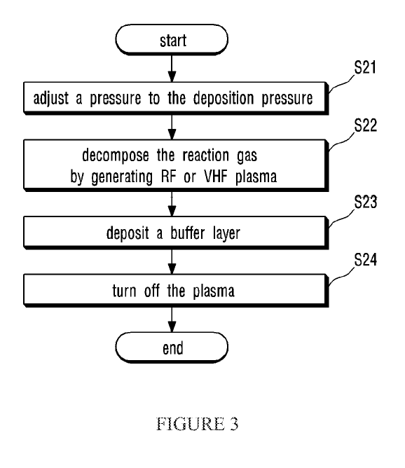

FIG. 2 shows a method for manufacturing a p-type window layer 30a of the photovoltaic device according to the embodiment of the present invention. FIG. 3 shows a method for manufacturing a buffer layer 30b of the photovoltaic device according to the embodiment of the present invention.

In the p-i-n type photovoltaic device, the first electrode 20 is formed on the substrate 10. The p-type window layer 30a is formed on the first electrode 20. The buffer layer 30b is formed on the p-type window layer 30a, and then the light absorbing layer 40, the n-type layer 50 and the second electrode 60 are sequentially formed.

In the n-i-p type photovoltaic device, the first electrode 20 is formed on the substrate 10, The n-type layer 50 is formed on the first electrode 20 prior to the p-type window layer 30a. The light absorbing layer 40 is formed on the n-type layer 50, and then the buffer layer 30b, the p-type window layer 30a and the second electrode 60 are formed in the order listed.

The p-type window layer 30a, the buffer layer 30b, the light absorbing layer 40 and the n-type layer 50 can be used in an top cell of a multi-junction photovoltaic device. Here, the top cell corresponds to a unit cell on which light is first incident among a plurality of unit cells included in the multi-junction photovoltaic device.

The p-type window layer 30a according to the embodiment of the present invention includes oxygen or carbon, and so the p-type window layer 30a has a large optical band gap. The buffer layer 30b prevents abrupt hetero-junction between the p-type window layer 30a and the light absorbing layer 40.

Accordingly, the p-type window layer 30a generates a strong electric field in the light absorbing layer 40 and absorbs minimal visible light by itself. Also, since the abrupt hetero-junction is prevented, recombination loss on an interface between the p-type window layer 30a and the light absorbing layer 40 is reduced.

As shown in FIG. 2, the substrate 10 is transferred to a p-layer deposition chamber so as to deposit the p-type window layer 30a (S11).

Here, the temperature of a substrate holder of the p-layer deposition chamber should be set to a deposition temperature and controlled (S12). The deposition temperature corresponds to an actual temperature of the substrate 10 at the time of which a slightly hydrogen-diluted p-type window layer 30a is deposited. The deposition temperature is equal to or higher than 100° C. and equal to or lower than 200° C. When the temperature is lower than 100° C., the deposition rate of the p-type window layer 30a is reduced, and a poor thin film having a high defect density is deposited. When the temperature is higher than 200° C., a transparent electrode is substantially etched by high energy hydrogen plasma, so that atoms of the thin film under the p-type window layer 30a are diffused to another thin film subsequently formed during the manufacture of the photovoltaic device. Such atoms function as impurity. As a result, quantum efficiency of the photovoltaic device Is reduced and photoelectric conversion efficiency is reduced as well.

For example, with regard to the p-i-n type photovoltaic device, when the first electrode 20 is zinc oxide, hydrogen functioning as a shallow donor of the zinc oxide flows out from a grain boundary or the surface of the zinc oxide at a temperature higher than 200° C. This may result in increasing the resistivity of the first electrode 20.

A refractive index of the first electrode 20 may be equal, to or less than 3.0 at a temperature lower than 200° C. This produces an anti-reflection effect by refractive index matching between the first electrode 20 and the light absorbing layer 40, so that the short-circuit current of the-photovoltaic device is increased.

After the substrate 10 is transferred to the p-layer deposition chamber, the pressure of the p-layer deposition chamber reaches a base pressure close to a vacuum by the operation of a high vacuum pump like a turbo molecular pump (S13). Here, the base pressure is equal to or greater than 10⁻⁷ Torr and equal to or less than 10⁻⁵ Torr. When the base pressure is less than 10⁻⁷, it is possible to deposit a high quality thin film having less contamination caused by impurity, but a deposition time becomes longer and the productivity is reduced. When the base pressure is greater than 10⁻⁵ Torr, it is not possible to obtain a high quality thin film because of contamination caused by impurity.

After the pressure of the p-layer deposition chamber reaches the base pressure, reaction gas is introduced into the deposition chamber. The pressure of the deposition chamber hereby reaches a deposition pressure (S14). The reaction gas includes silane gas (SiH₄), hydrogen gas (H₂), group III impurity gas, and carbon or oxygen source gas, Diborane (B₂H₆), TriMethylBoron (TMB), TriEthylBoron (TEB) and the like can be used as the group III impurity gas. Methan (CH₄), ethylene (C₂H₄), acetylene (C₂H₂) and the like can be used as the carbon source gas, O₂, CO₂ and the like can be used, as the oxygen source gas. The flow rate of each source gas is controlled by each mass flow controller (MFC).

When the pressure of the deposition chamber reaches a predetermined deposition pressure, the pressure of the deposition chamber is maintained constant by an angle valve and a pressure controller which are connected to the deposition chamber. The deposition pressure is set to a value for obtaining the thickness uniformity, high quality and appropriate deposition rate of the thin film. The deposition pressure is equal to or greater than 0.4 Torr and equal to or less than 2.5 Torr. When the deposition pressure is less than 0.4 Torr, the thickness uniformity and deposition rate of the p-type window layer 30a are reduced. When the deposition pressure is greater than 2.5 Torr, powder is produced at a plasma electrode within the deposition chamber or the manufacturing cost is increased due to the increase of the amount of gas consumed.

When the pressure within the deposition chamber is stabilized to the deposition pressure, the reaction gas within the deposition chamber is decomposed by means of either radio frequency plasma enhanced chemical vapor deposition (RF PECVD) using a frequency of 13.56 MHz or very high frequency plasma enhanced chemical vapor deposition (VHF PECVD) using a frequency greater than 13.56 MHz (S15). As a result, the slightly hydrogen-diluted p-type window layer 30a is deposited (S16).

The thickness of the p-type window layer 30a is equal to or larger than 12 nm and equal to or less than 17 nm. When the thickness of the p-type window layer 30a is less than 12 nm, conductivity becomes lower and so a strong electric field cannot be formed in an intrinsic light absorbing layer. Therefore, the open circuit, voltage of the photovoltaic device is low. When the thickness of the p-type window layer 30a is larger than 17 nm, light absorption by the p-type window layer 30a increases and the short-circuit current is reduced. Therefore, the conversion efficiency is reduced. Since the composition of the reaction gas is maintained constant during the deposition, the hydrogen-diluted p-type window layer 30a having a constant optical band gap is formed.

The electrical, conductivity of the p-type window layer 30a according to the embodiment of the present Invention is about 1×10⁻⁶S/cm, and the optical band gap of the p-type window layer 30a is about 2.0 eV. A silane concentration, i.e., an indicator of the hydrogen dilution ratio at the time of forming the p-type window layer 30a is equal to or greater than 4% and equal to or less than 10%. Here, the silane concentration is a ratio of the silane flow rate to a sum of the silane flow rate and the hydrogen flow rate.

When the silane concentration is less than 4%, the thin film which is located under the p-type window layer 30a is more damaged by activated hydrogen ions in the early stage of the deposition. In the p-i-n type photovoltaic device, the thin film under the p-type window layer 30a may be the first electrode 20. In the n-i-p type photovoltaic device, the thin film under the p-type window layer 30a may be the buffer layer 30b. When the silane concentration is greater than 10%, the deposition rate of the p-type window layer 30a is so high that it is difficult to control the thickness of the p-type window layer 30a, and besides, the degree of disorder within the window layer is increased, so that defect density such as a dangling bond is increased as well.

Additionally, the flow rates of the group III impurity gas, and carbon or oxygen source gas are determined as values for satisfying both the electrical characteristics and optical characteristics of the p-type window layer 30a.

When the concentration of the group III impurity gas becomes higher, the electrical conductivity of the p-type window layer 30a increases and the optical band gap of the p-type window layer 30a decreases. When the concentration of carbon or oxygen source gas becomes higher, the electrical conductivity of the p-type window layer 30a decreases and the optical band gap of the p-type window layer 30a increases.

The deposition of the p-type window layer 30a is finished by turning off the plasma (S17).

As shown, in FIG. 3, the buffer layer 30b is manufactured, by the following method.

Reaction, gas for forming the buffer layer 30b includes silane gas (SiH₄), hydrogen gas (H₂), group III impurity gas, and carbon or oxygen source gas. The group III impurity gas, carbon source gas and oxygen source gas have been described above, a description thereof will be omitted.

In the embodiment, of the present invention, when the p-type window layer 30a is composed of hydrogenated amorphous silicon oxide, the buffer layer 30b is composed of either hydrogenated amorphous silicon carbide or hydrogenated amorphous silicon oxide. That is, when the oxygen source gas is used to form the p-type window layer 30a, the carbon source gas or oxygen source gas can be used to form the buffer layer 30b.

In the embodiment of the present invention, when the p-type window layer 30a is composed of the hydrogenated amorphous silicon carbide, the buffer layer 30b is composed of the hydrogenated amorphous silicon oxide. Accordingly, when the carbon source gas is used to form the p-type window layer 30a, the oxygen source gas is used to form the buffer layer 30b. Additionally, the p-type window layer 30a is more slightly hydrogen-diluted than the buffer layer 30b, and the concentration of the impurity doped in the p-type window layer 30a is higher than the concentration of the impurity doped in the buffer layer 30b. Moreover, the carbon content of the p-type window layer 30a is larger than the oxygen content of the buffer layer 30b.

Since the p-type window layer 30a and buffer layer 30b are formed through the aforementioned method, the deposition pressures and the flow rates of the gases included in the reaction, gas during the forming of the p-type window layer 30a and buffer layer 30b.

When the buffer layer 30b is formed after the p-type window layer 30a is formed, or when the p-type window layer 30a is formed after the buffer layer 30b is formed, the deposition pressures and flow rates of the gases included in the reaction gas change. Therefore the angle valve connected to the pressure controller of the deposition chamber is fully opened and the flow rate setting of each of the mass flow controllers is changed into the deposition flow rate of the buffer layer or the deposition flow rate of the p-type window layer 30a.

Accordingly, the deposition pressure is controlled through adjusting the angle valve by setting the pressure of the pressure controller into the deposition pressure of the buffer layer (S21). The deposition pressure of the buffer layer 30b is equal to or greater 0.4 Torr and equal to or less than 2.5 Torr in consideration of the thickness uniformity, characteristic and appropriate deposition, rate of the thin film. When the deposition pressure of the buffer layer 30b is less than 0.4 Torr, the deposition rate and the thickness uniformity of the thin film are reduced. When the deposition pressure of the buffer layer 30b is greater than 2.5 Torr, powder is produced at a plasma electrode of the deposition chamber or the manufacturing cost is increased since the amount of gas used is increased.

When the pressure of the deposition chamber is stabilized to the deposition pressure, the reaction gas is decomposed in the deposition chamber by RF PECVD or VHF PECVD (S22). Accordingly, the buffer layer 30b more highly hydrogen-diluted than the p-type window layer 30a is deposited (S23).

The thickness of the buffer layer 30b is equal to or larger than 3 nm and equal to or less than 8 nm. When the thickness of the buffer layer 30b is less than 3 nm, the buffer layer 30b is not able to stably reduce the recombination at the interface between the p-type window layer 30a and the light absorbing layer 40. When the thickness of the buffer layer 30b is larger than 8 nm, light absorption by the buffer layer 30b increases and the short-circuit current is reduced. Therefore, the conversion efficiency is reduced due to the increase of series resistance.

Since the flow rates of the gases included in the reaction gas are maintained constant during the deposition of the buffer layer 30, the buffer layer 30b having a constant optical band gap can be formed. A silane concentration, i.e., an indicator of the hydrogen dilution ratio at the time of forming the buffer layer 30b is equal to or greater than 0.5% and equal to or less than 5%. When the silane concentration is less than 0.5%, the thin film under the buffer layer 30b may be damaged by high energy hydrogen ions. When the silane concentration is greater than 5%, the deposition rate is so high that it is difficult to control the thickness of the buffer layer 30b. Moreover the hydrogen dilution, is low and electrical conductivity is reduced, and so a high electric field may not be formed in an intrinsic light absorbing layer. Besides, the degree of disorder within the buffer layer 30b is increased, so that dangling bond density is increased as well.

Meanwhile, the impurity concentration of the buffer layer 30b is less than that of the p-type window layer 30a in order to prevent that the impurity contained in the p-type window layer 30a is diffused to the intrinsic light absorbing layer 40 so that quantum efficiency is reduced in a short wavelength range.

As such, a ratio of the flow rate of the impurity source gas to the flow rate of the silane is equal to or greater than 100 ppm and equal to or less than 2000 ppm in order both to prevent the impurity from being diffused to the light absorbing layer 40 and to maintain the electrical conductivity of the buffer layer 30b. When the ratio of the flow rate of the impurity source gas to the flow rate of the silane is greater than 100 ppm at the time of forming the buffer layer 30b, it is possible to prevent built-in potential from being reduced. When the ratio of the flow rate of the impurity source gas to the flow rate of the silane is less than 2000 ppm at the time of forming the buffer layer 30b, the impurity at the interface between the p-type window layer 30a and the light absorbing layer 40 can be prevented from being excessively diffused to the light absorbing layer 40.

A ratio of the flow rate of the impurity source gas to the flow rate of the silane is equal to or greater than 5000 ppm and equal to or less than 50000 ppm at the forming of the p-type window layer 30a. When the ratio of the flow rate of the impurity source gas to the flow rate of the silane is equal to or greater than 5000 ppm at the forming of the p-type window layer 30a, it is prevented that open circuit voltage and a fill factor are deteriorated due to the reduction of the electrical conductivity. When the ratio of the flow rate of the impurity source gas to the flow rate of the silane is equal to or less than 50000 ppm, it is possible to prevent an absorption coefficient and the recombination caused by dangling bond from being excessively increased.

The carbon or oxygen concentration of the buffer layer 30b is equal to or higher than 0.5 atomic % and equal to or less than 3 atomic % in order that the carbon or oxygen concentration and the optical band gaps of the slightly hydrogen-dilated p-type window layer 30a and the light absorbing layer 40 are prevented from rapidly being changed.

When the carbon or oxygen concentration of the buffer layer 30b is less than 0.5 atomic %, the concentration difference between, the p-type window layer 30a and the buffer layer 30b becomes larger and the defect density at the interface between the p-type window layer 30a and the buffer layer 30b becomes higher, so that the carrier recombination increases. When the carbon or oxygen content of the buffer layer 30b is higher than 3 atomic %, the conductivity of the buffer layer 30b is reduced and a high electric field is difficult to be formed in the light absorbing layer 40.

As described above, the electrical conductivity of the p-type window layer 30a is about 1×10⁻⁶ S/cm, and the optical band gap of the p-type window layer 30a is about 2.0 eV. For the purpose of the electrical conductivity and optical, band gap of the p-type window layer 30a, the oxygen content or carbon content of the p-type window layer 30a is equal to or more than 5 atomic % and equal to or less than 40 atomic %.

The deposition of the buffer layer 30b is finished by plasma-turn off (S24). The gas flow through all the mass flow controllers is stopped and the angle valve connected to the pressure controller is fully opened. As a result, the residual gases In the deposition chamber are exhausted through exhaust lines.

Meanwhile, in the embodiment of the present invention, when the p-type window layer 30a and the buffer layer 30b are composed, of hydrogenated amorphous silicon oxide, the p-type window layer 30a and the buffer layer 30b can be formed in one deposition chamber without an exhausting process. That is, gases of the same kind are used to form the p-type window layer 30a and the buffer layer 30b. Therefore, after the p-type window layer 30a or the buffer layer 30b is formed, another thin film is formed by controlling the flow rate of the gases and pressure without exhausting the gases within the deposition chamber.

In the embodiment of the present invention, when the p-type window layer 30a is composed of hydrogenated amorphous silicon oxide, the buffer laver 30b is composed of either hydrogenated amorphous silicon carbide or the hydrogenated amorphous silicon oxide. Also, when the p-type window layer 30a is composed of the hydrogenated amorphous silicon carbide, the buffer layer 30b is composed of the hydrogenated amorphous silicon oxide. Here, since the buffer layer 30b is more highly hydrogen-diluted than the p-type window layer 30a, it is possible to obtain a high electrical conductivity and a wide optical band gap even though the oxygen content or carbon content of the buffer layer 30b is small. Since the oxygen content or carbon content of the buffer layer 30b is reduced, the amount of the oxygen or carbon which is diffused to the light absorbing layer 40 is reduced and the degradation rate by light irradiation is also reduced as well.

While tire embodiment of the present invention has been described with reference to the accompanying drawings, it can be understood by those skilled in the art that the present invention can be embodied in other specific forms without departing from its spirit or essential characteristics. Therefore, the foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function, and not only structural equivalents but also equivalent structures.

What is claimed is:

1. A photovoltaic device comprising;
a first electrode;
a second electrode; and
a p-type window layer, a buffer layer, a light absorbing layer and an n-type layer, which are sequentially stacked between the first, electrode and the second electrode,
wherein, when the p-type window layer is composed of hydrogenated amorphous silicon oxide, the buffer layer is composed of either hydrogenated amorphous silicon carbide or hydrogenated amorphous silicon oxide,
and wherein, when the p-type window layer is composed of hydrogenated amorphous silicon carbide, the buffer layer is composed of hydrogenated amorphous silicon oxide.

2. The photovoltaic device of claim 1, wherein the hydrogen concentration of the buffer layer is greater than that of the p-type window layer.

3. The photovoltaic device of claim 2, wherein the hydrogen contents of the p-type window layer and the buffer layer are equal to or more than 10 atomic % and equal to or less than 25 atomic %.

4. The photovoltaic device of claim 1, wherein the impurity concentration of the buffer layer is less than that of the p-type window layer.

5. The photovoltaic device of claim 4, wherein the impurity concentration of the p-type window layer is equal to or greater than 1×10¹⁹ cm⁻³ and equal to or less than 1×10²¹ cm⁻³, and wherein the impurity concentration of the buffer layer is equal to or greater than 1×10¹⁶ cm⁻³ and equal to or less than 5×10¹⁹ cm⁻³.

6. The photovoltaic device of claim 1, wherein the thickness of the p-type window layer is equal to or larger than 12 nm and equal to or less than 17 nm.

7. The photovoltaic device of claim 1, wherein the thickness of the buffer layer is equal to or larger than 3 nm and equal to or less than 8 nm.

8. The photovoltaic device of claim 1, wherein the oxygen content or carbon content of the p-type window layer is equal to or more than 5 atomic % and equal to or less than 40 atomic %, and wherein the carbon content or oxygen content of the buffer layer is equal to or higher than 0.5 atomic % and equal to or less than 3 atomic %.

9. A method for manufacturing a photovoltaic device, the method comprising:
forming a first electrode;
forming a p-type window layer, a buffer layer, a light absorbing layer and an n-type layer, which are sequentially stacked on the first electrode in the order listed from a light incident side; and
forming a second electrode on the p-type window layer, the buffer layer, the light absorbing layer and the n-type layer, which are sequentially stacked from the light incident side,
wherein, the p-type window layer is composed of hydrogenated amorphous silicon carbide, the buffer layer is composed of hydrogenated amorphous silicon oxide,
wherein, when the buffer layer and the p-type window layer are formed, silane and impurity source gas are introduced into a process chamber,
wherein, when the p-type window layer is formed, a ratio of the flow rate of the impurity source gas to the flow rate of the silane is equal to or greater than 5000 ppm and equal to or less than 50000 ppm, and
wherein the carbon content of the p-type window layer is equal to or more than 5 atomic % and equal to or less than 40 atomic %.

10. The method of claim 9, wherein the hydrogen concentration of the buffer layer is greater than that of the p-type window layer.

11. The method of claim 9, wherein the impurity concentration of the buffer layer is less than that of the p-type window layer.

12. The method of claim 9, wherein, when the buffer layer is formed, a ratio of the flow rate of the impurity source gas to the flow rate of the silane is equal to or greater than 100 ppm and equal to or less than 2000 ppm.

13. The method of claim 9, wherein the thickness of the p-type window layer is equal to or larger than 12 nm and equal to or less than 17 nm.

14. The method of claim 9, wherein the thickness of the buffer layer is equal to or larger than 3 nm and equal to or less than 8 nm.

15. The method of claim 9, wherein the oxygen content of the buffer layer is equal to or higher than 0.5 atomic % and equal to or less than 3 atomic %.

16. The method of claim 9, wherein, when the p-type window layer is formed, the concentration of the silane introduced into a deposition chamber is equal to or greater than 4% and equal to or less than 10%.

17. The method of claim 9, wherein, when the buffer layer is formed, the concentration of the silane introduced into a deposition chamber is equal to or greater than 0.5% and equal to or less than 5%.

18. The method of claim 9, wherein the p-type window layer and the buffer layer are formed in one deposition chamber without an exhausting process.
